(19) United States
(12) Patent Application Publication
(10) Pub. No.: US 2026/0371974 A1
(43) Pub. Date: Nov. 19, 2026

(54) CMP INPUT STATION WITH HEATING SYSTEM

(71) Applicant: Taiwan Semiconductor Manufacturing Co., Ltd., Hsinchu (TW)

(72) Inventors: Jui Yu PAI, Hsinchu (TW); Chen-Hsueh LIN, Hsinchu (TW); Jeng-Chi LIN, Hsinchu (TW); Chi-Hsiang SHEN, Hsinchu (TW); Tang-Kuei CHANG, Hsinchu (TW); Te-Chien HOU, Hsinchu (TW)

(73) Assignee: Taiwan Semiconductor Manufacturing Co., Ltd., Hsinchu (TW)

(21) Appl. No.: 19/207,103

(22) Filed: May 13, 2025

(51) Int. Cl. H10P 52/00; H10P 72/00

(52) U.S. Cl. CPC H10P 52/00; H10P 72/0408; H10P 72/0412; H10P 72/0414; H10P 72/0436

(57) ABSTRACT

A chemical mechanical planarization (CMP) system includes a polisher and a cleaning station. The polisher performs a CMP process on a wafer. The cleaning station receives the wafer after the CMP process and sprays a cleaning fluid onto the wafer. The cleaning system also includes a heating system configured to heat the cleaning fluid. The heated cleaning fluid removes contaminants from the wafer.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

Chemical mechanical planarization (CMP) is a process that has enabled the use of thin film materials that enable features of relatively small size. CMP can planarize the surface of a semiconductor wafer after thin film deposition and patterning processes. CMP utilizes chemical and mechanical processes to planarize the semiconductor wafer. After a CMP process, it is possible than an exposed metal layer may oxidize or that there may be debris on the surface of the wafer.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF DESCRIPTION OF THE DRAWINGS

FIG. 1 is an illustration of a CMP system, in accordance with some embodiments.

FIG. 2 is a cross-sectional view of a cleaning station of a CMP system, in accordance with some embodiments.

FIG. 3 is a cross-sectional view of a cleaning station of a CMP system, in accordance with some embodiments.

FIGS. 4-16 are top views of various cleaning stations of CMP systems, in accordance with some embodiments.

FIG. 17 is an illustration of a heating coil of a cleaning station of a CMP system, in accordance with some embodiments.

FIG. 18 is an illustration of a cleaning fluid distributor of a cleaning station of a CMP system, in accordance with some embodiments.

FIG. 19 is an illustration of a brush station of a CMP system, in accordance with some embodiments.

FIG. 20 is an illustration of a dryer station of a CMP system, in accordance with some embodiments.

FIG. 21 is a flow diagram of a method for operating a CMP system, in accordance with some embodiments.

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

As used in this specification, “light” generally refers to electromagnetic radiation of any wavelength, except where a particular band or wavelength is specified.

As used in this specification, “reticle” corresponds to a photolithography mask or photomask.

Embodiments of the present disclosure provide a cleaning station for a CMP system, in accordance with some embodiments. After a CMP process, it is possible that an exposed metal layer can oxidize. Furthermore, it is possible that debris or other unwanted particles or contaminants can remain on the surface of the wafer after the CMP process. After a CMP process has been performed on a wafer, the wafer is passed to a cleaning station. The cleaning station rinses the wafer with a cleaning fluid. The cleaning station, in accordance with embodiments of the present disclosure, includes a heating system that heats the cleaning fluid or that heats the interior of the cleaning station while the wafer is being rinsed. The elevated temperature results in a greatly increased ability of the cleaning fluid to remove metal oxides and other debris from the surface of the wafer. The heating system can include one or both of a heater that radiates heat and a device that blows hot air into the cleaning station. This elevates a temperature of the cleaning fluid, resulting in an increased ability of the cleaning fluid to remove metal oxides and to clean debris from the surface of the wafer.

Embodiments of the present disclosure provide many benefits over traditional cleaning stations of CMP systems. For example, after the wafer has been cleaned by the cleaning station, the wafer is passed to a brush station the uses one or more brushes to further condition the surface of the wafer. If there are debris particles or metal oxides on the surface of the wafer, it is possible that the brushes will become heavily contaminated or loaded with metal oxide particles are debris particles. This could result in stoppage of the CMP system until the brushes can be cleaned or replaced. Embodiments of the present disclosure help ensure that the brushes are not contaminated and that CMP processes are not interrupted. Furthermore, semiconductor wafer yields are increased and integrated circuits formed in the semiconductor wafers function properly.

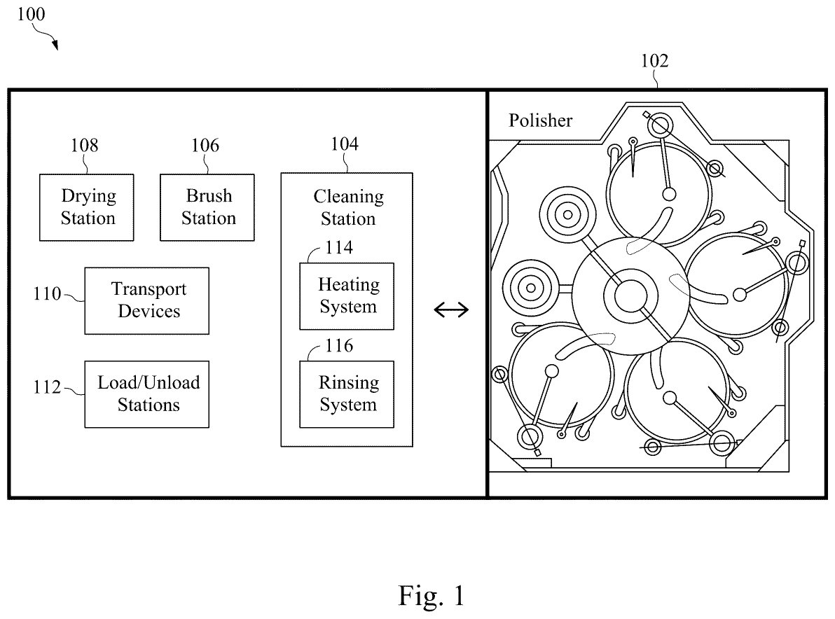

FIG. 1 is an illustration of a CMP system 100, in accordance with some embodiments. The CMP system 100 includes a polisher 102, a cleaning station 104, one or more brush stations 106, and a drying station 108. As will be set forth in more detail below, the cleaning station 104 is configured to effectively remove exposed metal oxides or debris particles from the surface of a wafer. This further enables the productive operation of the brush stations 106 and the drying station 108.

In some embodiments, the polisher 102 includes two main polishing stations and two chemical buff stations. The main polishing stations and the two chemical buff stations perform the CMP processes on the wafers. Each polishing/buff station includes a platen. The platen is configured to rotate during CMP processes. The platen may rotate with a rotational velocity of between 20 RPM and 40 RPM, though other rotational velocities can be utilized without departing from the scope of the present disclosure. The platen may have a diameter of about 50 cm to 75 cm, though platens of other sizes can be utilized without departing from the scope of the present disclosure.

At each polishing/buff station, a CMP pad is positioned on top of the platen. The CMP pad may be circular and may have a diameter that is substantially identical to the diameter of the platen. The CMP pad may be coupled to the platen by fasteners, by suction (i.e., pressure differential), by electrostatic force, or in any suitable way. When the platen rotates, the CMP pad also rotates. The rotation of the CMP pad is one of the factors that planarizes the semiconductor wafer, as will be described in more detail below.

The CMP pad can be made of a porous material. In one example, the CMP pad is made from a polymeric material having a pore size between 20 micrometers and 50 micrometers. The CMP pad may have a roughness of about 50 μm. Other materials, dimensions, and structures of a CMP pad can be utilized without departing from the scope of the present disclosure. The CMP pad may be substantially rigid.

A slurry supply system supplies a slurry onto the rotating pad during the CMP process. In particular, the slurry supply system may have a plurality of nozzles or apertures that each output the slurry onto the pad. The slurry can include a solution of water and one or more corrosive compounds. The corrosive compounds are selected to chemically etch or remove one or more materials on the surface of the semiconductor wafer. Accordingly, the compounds in the slurry are selected based on the material or materials of the surface features of the semiconductor wafer to be planarized. The slurry supply system can include a tank that holds the slurry and a tube or hose that delivers the slurry onto the rotating CMP pad during the CMP process.

The pad conditioner conditions the rotating CMP pad during the CMP process. During the CMP process, the top surface of the rotating CMP pad experiences wear from the planarization process. The top surface of the rotating pad may wear out unevenly such that depressions, valleys, and peaks may form in the CMP pad. The pad conditioner includes a rotating pad conditioner head that is pressed downward onto the rotating CMP pad. The rotating pad conditioner head includes or is coated with a hard, durable material that can effectively sand down the surface of the CMP pad. In one example, the surface of the pad conditioner includes a diamond material. The rotating head of the pad conditioner sweeps across the surface of the rotating CMP pad in a pattern selected to maintain a substantially even top surface of the CMP pad during the CMP process. Accordingly, the pad conditioner removes or prevents the formation of depressions, ridges, valleys, or uneven features on the surface of the rotating CMP pad.

During the CMP process, the CMP head places the downward facing surface of the semiconductor wafer into contact with the rotating CMP pad. The CMP head may also rotate the semiconductor wafer during the CMP process. Surface features of the downward facing surface of the semiconductor wafer are planarized during the CMP process. The planarization is achieved by both mechanical and chemical processes. The mechanical aspect of the planarization is achieved by the physical effect of the CMP pad rubbing down the bottom facing surface of the semiconductor wafer. The mechanical aspect of the planarization is akin to a very fine sanding process. The chemical aspect of the planarization is achieved by the chemical effect of the slurry on the materials of the surface features of the semiconductor wafer. The compounds in the solution of the slurry etch or otherwise react with and remove the materials of the surface features of the semiconductor wafer. The result of the CMP process is that the exposed bottom facing surface of the semiconductor wafer becomes substantially planar.

In some embodiments, the CMP process is utilized to remove excess metal material from a top surface of the wafer in order to form metal tracks or conductive vias in a dielectric layer. After the CMP process, the top surfaces of the conductive vias and metal tracks are exposed. It is possible that some of the exposed metal may oxidize. Additionally, it is possible that debris, or other types of particles from the CMP process may remain on the surface of the wafer after the CMP process.

The CMP system includes the cleaning station 104, the brush stations 106, and the drying station 108 to clean and condition the surface of the wafer after the CMP process. The cleaning station may be termed an input station that receives the wafers from the polisher 102 and performs an initial rinsing of the wafers. Further details regarding the cleaning station 104 are provided below.

The CMP system 100 includes transport devices 110. The transport devices 110, transfer the wafers between stations of the CMP system 100. The transport devices 110 include a plurality of robot arms and other transport mechanisms that transfer the wafers between the stations of the CMP system 100.

The CMP system 100 includes load/unload stations 112. The load/unload stations 112 receive wafers from systems external to the CMP system 100 so that the CMP system 100 can perform CMP processes on the wafers. The load/unload stations 112 also unload wafers from the CMP system 100. Various other components and systems can be utilized to transport wafers and to load and unload wafers without departing from the scope of the present disclosure.

The cleaning station 104 receives wafers from the polisher 102 after CMP processes have been performed at the polishing and buffing stations of the polisher 102. As described previously, in some cases it is possible that the top surfaces of exposed metals on the wafer can oxidize after the CMP processes, resulting in the presence of undesired metal oxide on the surface of the wafer. Additionally, debris and other unwanted particles may be present at the surfaces of the wafer after the CMP process.

The cleaning station 104 is utilized to clean the surfaces of the wafer after the CMP processes. The cleaning station 104 removes undesired metal oxide from the surface of the wafer. Cleaning station 104 also removes other types of unwanted debris from the surface of the wafer. In some embodiments, the cleaning station 104 is an input station of the CMP system 100.

In some embodiments, the cleaning station 104 includes a heating system 114 and a rinsing system 116. The rinsing system 116 supplies a high-pressure stream of a cleaning fluid onto the surface of the wafer. The stream of high-pressure cleaning fluid helps to remove metal oxide or other unwanted contaminants from the surface of the wafer. In some embodiments, the cleaning fluid is deionized water. In some embodiments, the cleaning fluid is a cleaning chemical. In some embodiments, the cleaning chemical includes ethylene glycol. Other cleaning chemicals or cleaning fluids can be utilized without departing from the scope of the present disclosure.

The heating system 114 is utilized to enhance the cleaning function of the rinsing system 116. If the cleaning fluid is supplied onto the wafer at room temperature, the etching rate of a metal oxide, such as WO3, occurs at a first etching rate. If the cleaning fluid is supplied onto the wafer at an elevated temperature, the etching rate of the metal oxide increases dramatically. For example, if the temperature of the cleaning fluid is between 55° and 65 °C, then the metal oxide is etched at a second rate that is around 30 times greater than the first rate. This increased etching rate is sufficient to thoroughly remove metal oxide from the top surface of the wafer. Furthermore, the heated cleaning fluid is much more effective at removing other debris or contaminants that have fallen onto the surface of the wafer.

In some embodiments, the heating system 114 heats the cleaning fluid before the cleaning fluid is output from the rinsing system 116. In some embodiments, the heating system 114 heats the environment within the cleaning station 104 such that the cleaning fluid is heated as the cleaning fluid travels toward the wafer. In some embodiments, the heating system 114 heats the wafer so that the temperature of the cleaning fluid is elevated when the cleaning fluid impacts the surface of the wafer. In each of the scenarios, the removal of metal oxides and other particles or contaminants is increased significantly.

In some embodiments, the heating system 114 includes a heater that heats the interior of the cleaning station 104 via radiative heating. In some embodiments, the heater includes a halogen lamp. The halogen lamp heats up during operation, thereby radiating heat throughout the interior of the in order to raise the temperature of the cleaning station 104. In some embodiments, the heater includes a heating coil. An electric current is passed through the heating coil, thereby raising the temperature of the heating coil. The heating coil heats the interior of the cleaning station 104.

In some embodiments, the heating system 114 includes a heater that blows a heated gas into the interior of the cleaning station 104. In some embodiments, the heated gas is a highly purified air. In some embodiments, the heated gas includes an inert gas such as argon, helium, or molecular nitrogen. The heated gas air interacts with the cleaning fluid and heats the cleaning fluid. The heated gas also interacts with the wafer, thereby heating the wafer. The increased temperature of the cleaning fluid and the wafer results in a greatly increased etching of the metal oxide or other debris from the surface of the wafer.

Though not shown in FIG. 1, in some embodiments, the cleaning station 104 includes a preclean station. At the preclean station, cleaning fluid is sprayed onto the wafer while a roller rotates the wafer. The heating system 114 can be utilized in the preclean station. In some embodiments, the preclean station is separate from the cleaning station 114.

In some embodiments, the CMP system 100 includes a washing tank (not shown in FIG. 1). After the wafer is passed from the cleaning station 104, the wafer is passed to the washing tank. A transfer device lowers the wafer edgewise into the washing tank. The washing tank is filled with deionized water. The wafers are washed in the deionized water and removed from the washing tank.

The CMP system 100 includes a brush station 106. After the wafer passes from the cleaning station 104, the wafer is transported to the brush station 106. In some embodiments, the wafer is lowered edgewise into the brush station 106. The brush station 106 includes rotating brushes that clean the surface of the wafers. The brush station also includes chemical spray bars that spray chemicals onto the wafers while the brushes clean the wafers. In some embodiments, the brushes modify the surface affinity of the wafer in preparation for subsequent processes.

In the absence of the heating system 116 at the cleaning station 104, it is possible that the surface of the wafer could still include debris particles and metal oxide after exiting the cleaning station 104. It wafers are passed to the brush station 106 with large amounts of metal oxide or debris particles on the surface, it is possible that over time the brushes will become loaded with debris particles. Such a state of the brushes may call for the brushes to be removed and cleaned. During this time, the throughput of the CMP system is halted until the brush stations 106 become operational again. This can be highly expensive.

Advantageously, the cleaning station 104 utilizes the heating system 116 to help ensure that the brushes remain clean and unloaded. This results from the cleaning station 114 effectively removing metal oxide and other contaminant particles by heating one or both of the wafer and the cleaning fluid at the cleaning station 104.

In some embodiments, the 100 includes a drying station 108. In some embodiments, the drying station 108 is a vapor dryer. At the drying station, a transportation device lowers the wafers into the vapor dryer. The vapor dryer uses vapor action to push water and any remaining chemicals from the surface of the wafers. Other types of drying stations can be utilized without departing from the scope of the present disclosure.

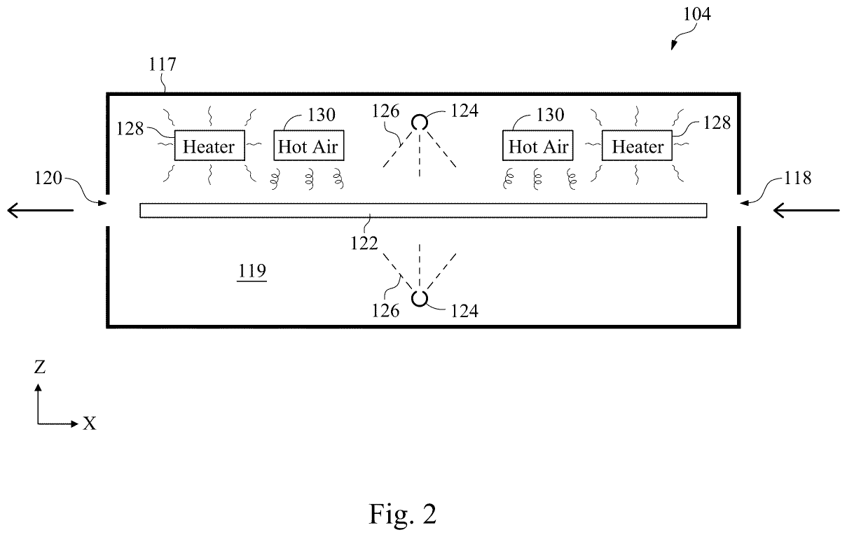

FIG. 2 is a cross-sectional view of a cleaning station 104, in accordance with some embodiments. The cleaning station 104 is one example of a cleaning station 104 of FIG. 1. The cleaning station 104 includes a housing 117. The housing 117 defines an interior volume 119. The housing 117 includes a first opening 118 and a second opening 120. A semiconductor wafer 122 is received at the opening 118, is passed through the interior volume 119, and is passed from the interior volume 119 through the opening 120. As will be set forth in more detail below, the cleaning station 104 cleans the semiconductor wafer 122 while the semiconductor wafer 122 is within the housing 117.

The cleaning station 104 includes cleaning fluid distributors 124, in accordance with some embodiments. Each cleaning fluid distributor 124 includes one or more nozzles or openings. Each cleaning fluid distributor 124 outputs a high-pressure stream of cleaning fluid 126 onto the wafer 122. The cleaning fluid 126 cleans metal oxide and other debris particles or contaminants from the surfaces of the wafer 122. The cleaning fluid distributors 124 are examples of a rinsing system 116 of FIG. 1.

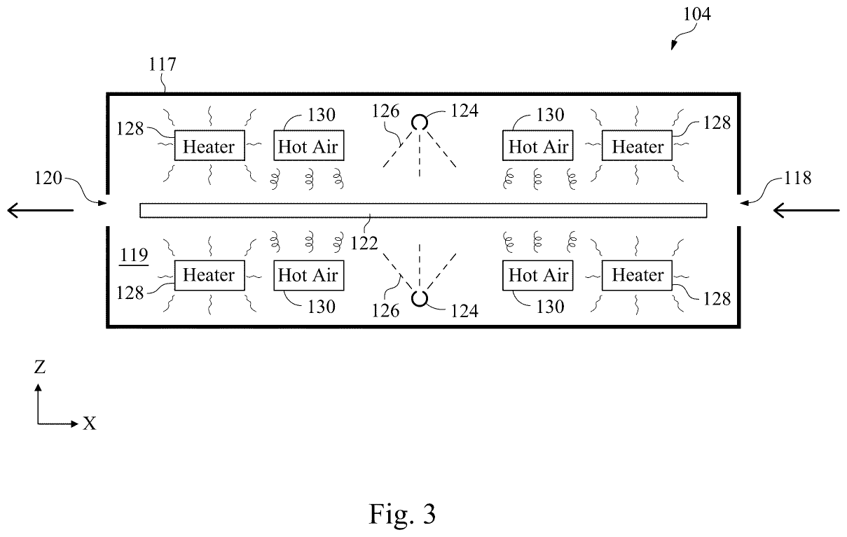

The cleaning station 104 includes one or more heaters 128 and one or more hot air distributors 130. The one or more heaters 128 and the one or more hot air distributors 130 correspond to examples of a heating system 114 of FIG. 1. In practice, the hot air distributors 130 may also be termed heaters. In the view of FIG. 1, the heaters 128 and the hot air distributors 130 are positioned above the wafer 122. More particularly, the heaters 128 and the hot air distributors 130 are positioned above the surface of the wafer 122 on which metal structures are exposed after a CMP process. As will be set forth in relation to FIG. 3, in some embodiments, the heaters 128 and the hot air distributors 130 are also positioned below the wafer 122. In some embodiments, the cleaning station 104 includes one or more heaters 128 without any hot air distributors 130. In some embodiments, the cleaning station 104 includes one or more hot air distributors 130 without any heaters 128. As will be set forth in more detail below, various combinations of heating components can be utilized without departing from the scope of the present disclosure.

The heaters 128 and hot air distributors 130 are utilized to enhance the cleaning function of the cleaning fluid 126. As set forth previously, the cleaning fluid 126 etches or removes metal oxides and debris particles at a much higher rate if one or both of the cleaning fluid 126 and the surface of the wafer 122 are at an elevated temperature with respect to room temperature. For example, if the temperature of the cleaning fluid/wafer 122 is between 55° and 65 °C, then the metal oxide is etched at a much higher rate than at room temperature (about 22 °C). This increased etching rate is sufficient to thoroughly remove metal oxide from the top surface of the wafer. Furthermore, the heated cleaning fluid is much more effective at removing other debris or contaminants that have fallen onto the surface of the wafer.

In some embodiments, the heater 128 is a radiative heater that heats the interior of the cleaning station 104 via radiative heating. In some embodiments, the heater 128 includes a halogen lamp. The halogen lamp heats up during operation, thereby radiating heat throughout the interior 119 of the cleaning station 104 in order to raise the temperature of the wafer 122 and the cleaning fluid 126.

In some embodiments, the heater 128 includes a heating coil. A current is passed to the heating coil, thereby raising the temperature of the heating coil. The heating coil heats the interior 119 of the cleaning station 104. Other types of radiative heaters can be utilized without departing from the scope of the present disclosure.

In some embodiments, the hot air distributor 130 blows a heated gas into the interior of the cleaning station 104. In some embodiments, the heated gas is a highly purified air. In some embodiments, the heated gas includes an inert gas such as argon, helium, or molecular nitrogen. The heated gas air interacts with the cleaning fluid and heats the cleaning fluid. The heated gas also interacts with the wafer 122, thereby heating the wafer. The increased temperature of the cleaning fluid 126 and the wafer 122 results in a greatly increased removal rate of the metal oxide or other debris from the surface of the wafer.

In some embodiments, the hot air distributor 130 outputs highly purified air (or other heated gas). Accordingly, the hot air distributor 130 can include a gas source and a plurality of filters. The gas source supplies the heated gas (air or other gas) to the one or more filters. The filters collectively purify the heated gas until the heated gas is purified to satisfy clean room standards. Alternatively, the gas can be heated after purification. The heated gas is then output into interior 119 of the cleaning station 104.

In some embodiments, the cleaning fluid 126 is heated prior to being output from the cleaning fluid distributor 124. In some embodiments, hot air is introduced into the cleaning fluid distributor 126 to mix with and heat the cleaning fluid 126 as the cleaning fluid is output from the cleaning station 104.

FIG. 3 is a cross-sectional view of a cleaning station 104, in accordance with some embodiments. The cleaning station 104 of FIG. 3 is substantially similar to the cleaning station 104 of FIG. 2 in many regards. In FIG. 3, heaters 128 and hot air distributors 130 are positioned below the wafer 122. This can increase the efficiency and effectiveness of cleaning of the bottom of the wafer 122. The layout and distribution of heaters 128 and hot air distributors 130 below the wafer 122 can be the same or different from the layout and distribution of heaters 128 and hot air distributors 130 above the wafer 122.

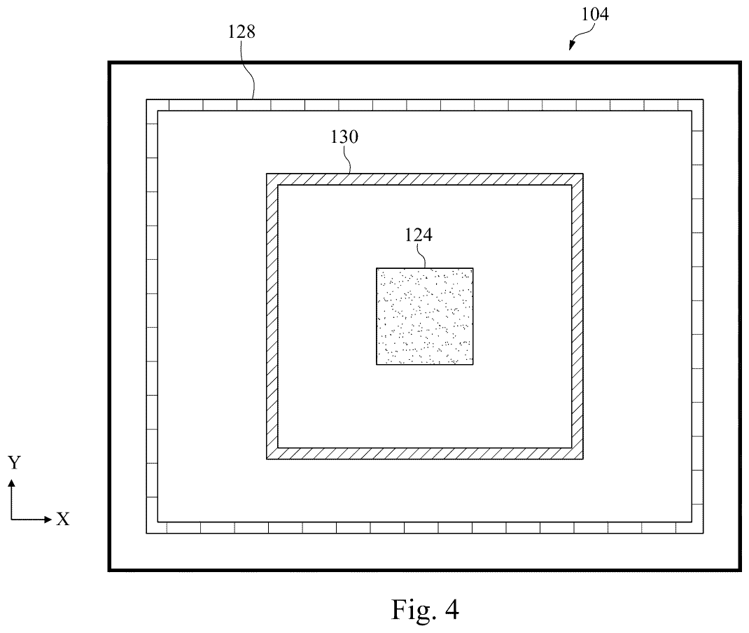

FIG. 4 is a top view of a layout of cleaning fluid distributors 124, heaters 128, and hot air distributors 130 within a cleaning station 104, in accordance with some embodiments. The layout of FIG. 4 can correspond to the layout above the wafer 122 or below the wafer 122. The layout above the wafer 122 can be the same as or different from the layout below the wafer 122.

In FIG. 4, a cleaning fluid distributor 124 is centrally positioned, in accordance with some embodiments. This can correspond to a single nozzle or multiple nozzles distributing the cleaning fluid 126 in a central location of the layout.

In FIG. 4, a hot air distributor 130 laterally surrounds the cleaning fluid distributor 124, in accordance with some embodiments. The hot air distributor 130 can correspond to a plurality of individual hot air distributors 130 or a single continuous hot air distributor 130. In some embodiments, the hot air distributor 130 includes a plurality of discrete vents that blow hot air into the interior of the cleaning station 104. In some embodiments, the hot air distributor 130 includes a single continuous vent.

In FIG. 4, a heater 128 laterally surrounds the hot air distributor 130, in accordance with some embodiments. The heater 128 can correspond to a plurality of individual heaters 128 or a continuous heater 128. In some embodiments, the heater 128 includes a single halogen lamp that continuously laterally surrounds the hot air distributor 130. In some embodiments, the heater 128 includes a plurality of halogen lamps that collectively laterally surround the hot air distributor 130. In some embodiments, the heater 128 includes a single heating coil that laterally surrounds the hot air distributor 128. In some embodiments, the heater 128 includes a plurality of heating coils that collectively laterally surround the hot air distributor 130.

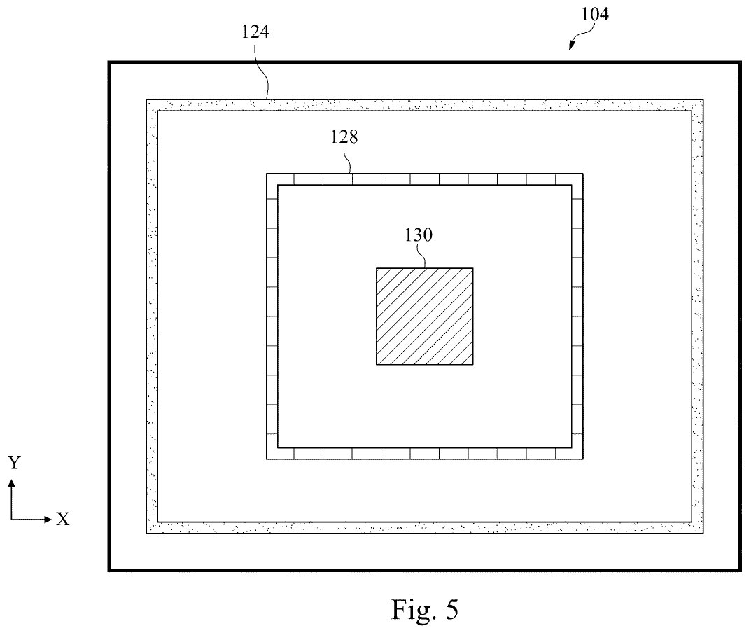

FIG. 5 is a top view of a layout of cleaning fluid distributors 124, heaters 128, and hot air distributors 130 within a cleaning station 104, in accordance with some embodiments. In FIG. 5, a hot air distributor 130 is centrally positioned, in accordance with some embodiments. This can correspond to a single hot air distributor 130 or multiple hot air distributors 130 distributing the heated gas in a central location of the layout.

In FIG. 5, a heater 128 laterally surrounds the hot air distributor 130, in accordance with some embodiments. The heater 128 can correspond to a plurality of individual heaters 128 or a continuous heater 128. In some embodiments, the heater 128 includes a single halogen lamp that continuously laterally surrounds the hot air distributor 130. In some embodiments, the heater 128 includes a plurality of halogen lamps that collectively laterally surround the hot air distributor 130. In some embodiments, the heater 128 includes a single heating coil that laterally surrounds the hot air distributor 128. In some embodiments, the heater 128 includes a plurality of heating coils that collectively laterally surround the hot air distributor 128.

In FIG. 5, a cleaning fluid distributor 124 laterally surrounds the heater 128, in accordance with some embodiments. The cleaning fluid distributor 124 can correspond to a plurality of individual cleaning fluid distributors 124 or a continuous cleaning fluid distributor 124. In some embodiments, the cleaning fluid distributor 124 includes a plurality of fluid distribution bars that each include a plurality nozzles or openings that output cleaning fluid 126 onto the wafer 122. In some embodiments, the cleaning fluid distributor 124 includes a single structure including a plurality of nozzles or openings.

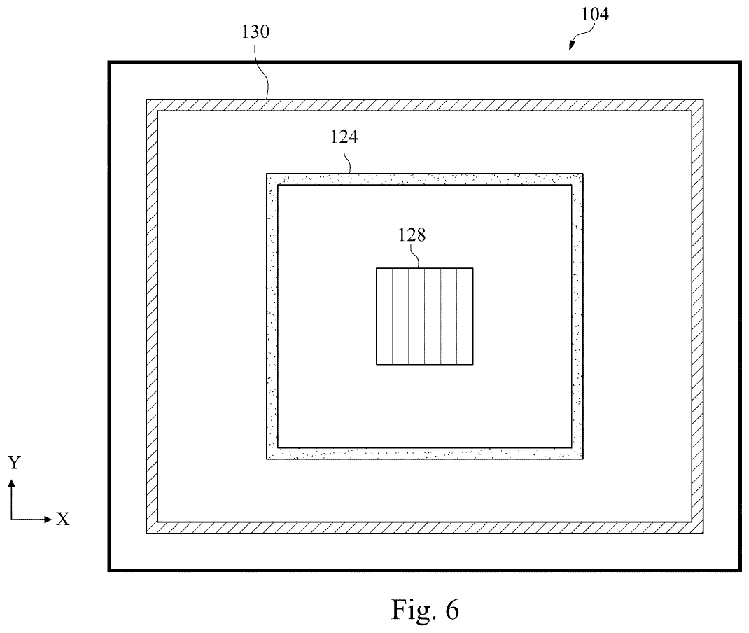

FIG. 6 is a top view of a layout of cleaning fluid distributors 124, heaters 128, and hot air distributors 130 within a cleaning station 104, in accordance with some embodiments. In FIG. 6, a heater 128 is centrally positioned, in accordance with some embodiments. A cleaning fluid distributor 124 laterally surrounds the heater 128. A hot air distributor laterally surrounds the cleaning fluid distributor 124.

In some embodiments, the cleaning fluid distributors 124, heaters 128, and hot air distributors 130 of FIGS. 4-6 have lateral dimensions in the X direction between 3 cm and 80 cm. In some embodiments, the cleaning fluid distributors 124, heaters 128, and hot air distributors 130 of FIGS. 4-6 have lateral dimensions in the Y direction between 3 cm and 80 cm.

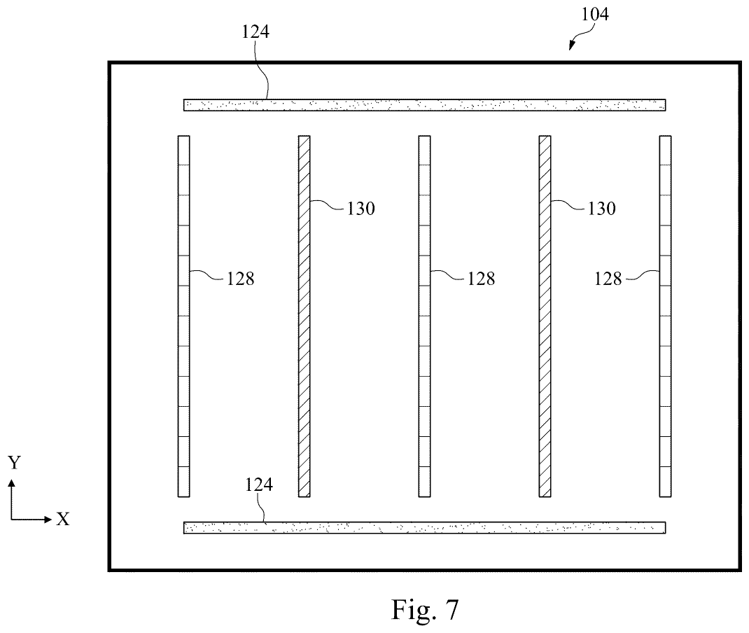

FIG. 7 is a top view of a layout of cleaning fluid distributors 124, heaters 128, and hot air distributors 130 within a cleaning station 104, in accordance with some embodiments. In FIG. 7, two cleaning fluid distributors 124 extend in the X direction along the edges of the interior volume of the cleaning station 104. A first heater 128 extends in the Y direction at the left end of the cleaning station 104. A first hot air distributor 130 extends in the Y direction to the right of the first heater 128. A second heater 128 extends in the Y direction to the right of the first hot air distributor 130. A second hot air distributor 130 extends in the Y direction to the right of the second heater 128. A third heater 128 extends in the Y direction to the right of the hot air distributor 130 along the right end of the cleaning station 104.

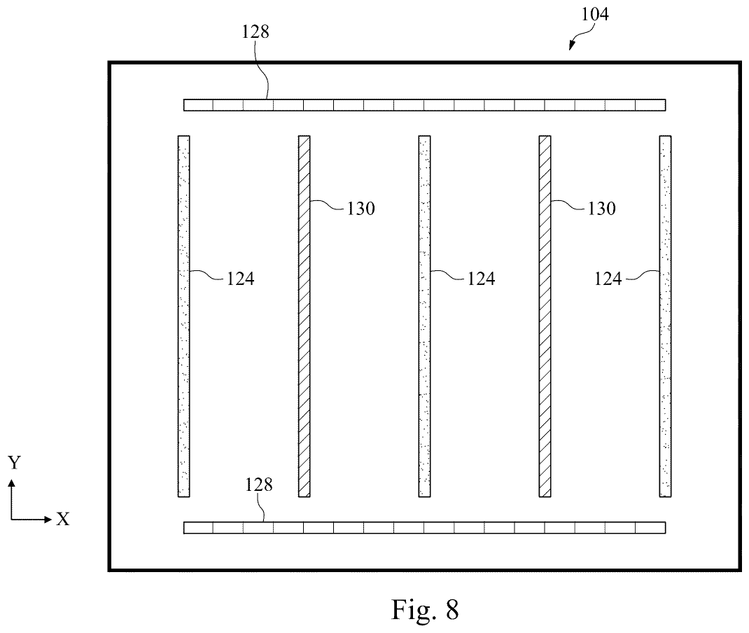

FIG. 8 is a top view of a layout of cleaning fluid distributors 124, heaters 128, and hot air distributors 130 within a cleaning station 104, in accordance with some embodiments. In FIG. 8, two heaters 128 extend in the X direction along the edges of the interior volume of the cleaning station 104. A first cleaning fluid distributor 124 extends in the Y direction at the left end of the cleaning station 104. A first hot air distributor 130 extends in the Y direction to the right of the first cleaning fluid distributor 124. A second cleaning fluid distributor 124 extends in the Y direction to the right of the first hot air distributor 130. A second hot air distributor 130 extends in the Y direction to the right of the second cleaning fluid distributor 124. A third cleaning fluid distributor 124 extends in the Y direction to the right of the second hot air distributor 130 along the right end of the cleaning station 104.

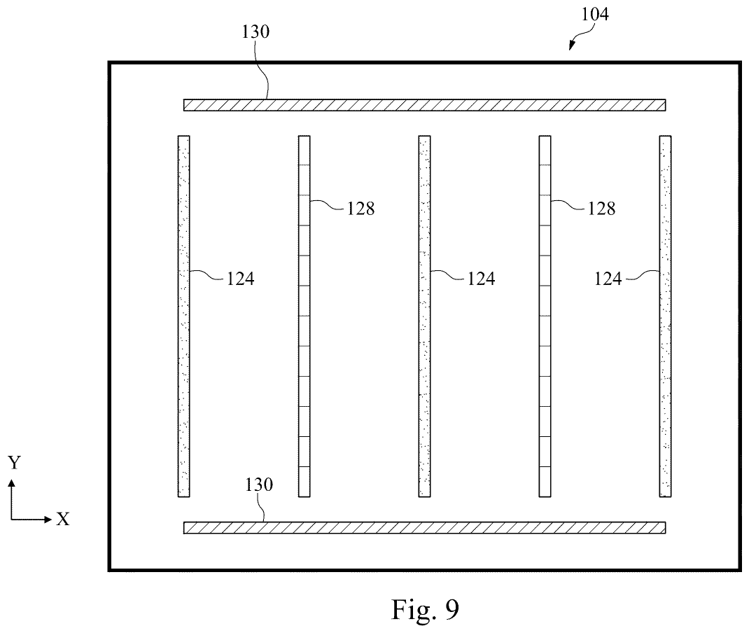

FIG. 9 is a top view of a layout of cleaning fluid distributors 124, heaters 128, and hot air distributors 130 within a cleaning station 104, in accordance with some embodiments. In FIG. 9, two hot air distributors 130 extend in the X direction along the edges of the interior volume of the cleaning station 104. A first cleaning fluid distributor 124 extends in the Y direction at the left end of the cleaning station 104. A first heater 128 extends in the Y direction to the right of the first cleaning fluid distributor 124. A second cleaning fluid distributor 124 extends in the Y direction to the right of the first heater 128. A second heater 128 extends in the Y direction to the right of the second cleaning fluid distributor 124. A third cleaning fluid distributor 124 extends in the Y direction to the right of the second heater 128 along the right end of the cleaning station 104.

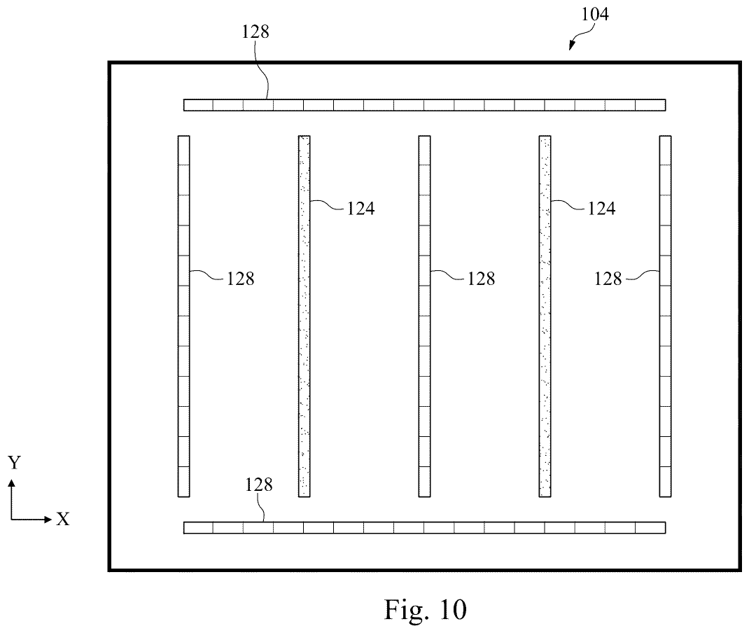

FIG. 10 is a top view of a layout of cleaning fluid distributors 124 and heaters 128 within a cleaning station 104, in accordance with some embodiments. In FIG. 10, two heaters 128 extend in the X direction along the edges of the interior volume of the cleaning station 104. A first hot air distributor 130 extends in the Y direction at the left end of the cleaning station 104. A first cleaning fluid distributor extends in the Y direction to the right of the first hot air distributor 130. A second hot air distributor 130 extends in the Y direction to the right of the first cleaning fluid distributor 124. A second cleaning fluid distributor extends in the Y direction to the right of the second hot air distributor 130. A third hot air distributor 130 extends in the Y direction to the right of the second cleaning fluid distributor 124 along the right end of the cleaning station 104.

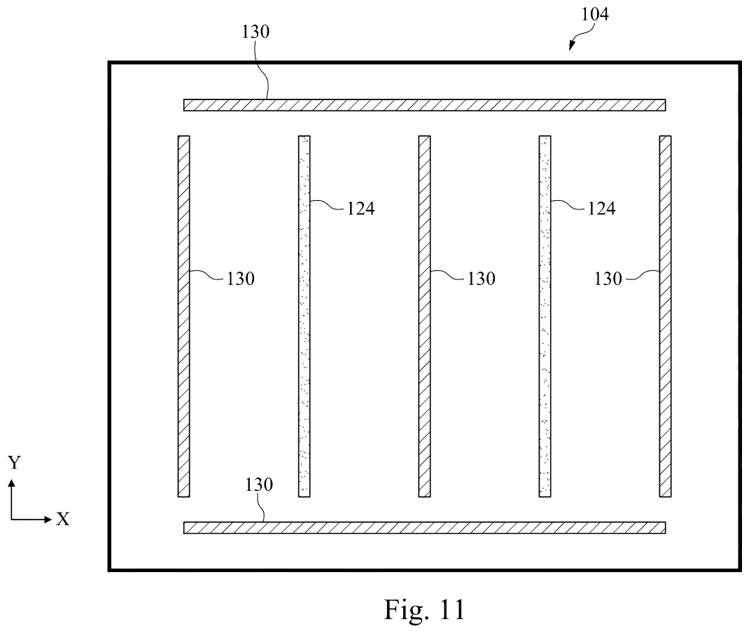

FIG. 11 is a top view of a layout of cleaning fluid distributors 124 and hot air distributors 130 within a cleaning station 104, in accordance with some embodiments. In FIG. 11, two hot air distributors extend in the X direction along the edges of the interior volume of the cleaning station 104. A first hot air distributor 130 extends in the Y direction at the left end of the cleaning station 104. A first cleaning fluid distributor extends in the Y direction to the right of the first hot air distributor 130. A second hot air distributor 130 extends in the Y direction to the right of the first cleaning fluid distributor 124. A second cleaning fluid distributor extends in the Y direction to the right of the second hot air distributor 130. A third hot air distributor 130 extends in the Y direction to the right of the second cleaning fluid distributor 124 along the right end of the cleaning station 104.

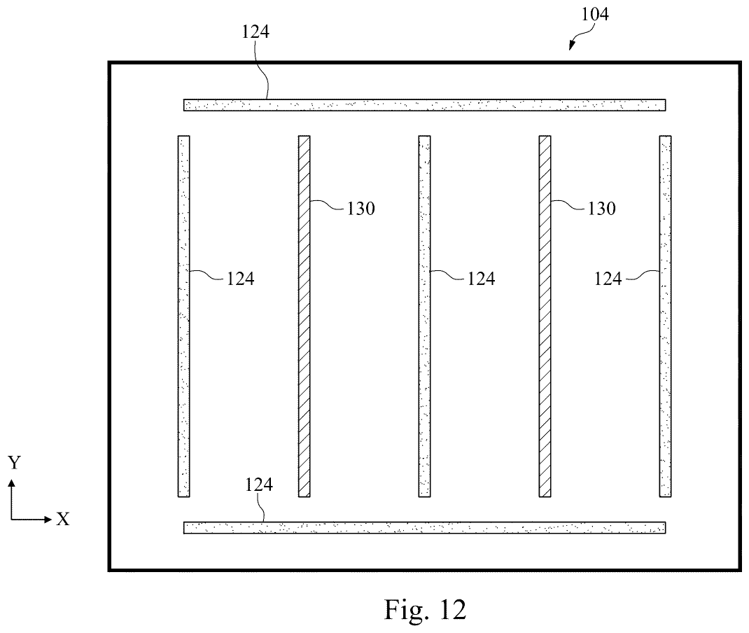

FIG. 12 is a top view of a layout of cleaning fluid distributors 124 and hot air distributors 130 within a cleaning station 104, in accordance with some embodiments. In FIG. 12, two cleaning fluid distributors 124 extend in the X direction along the edges of the interior volume of the cleaning station 104. A first cleaning fluid distributor 124 extends in the Y direction at the left end of the cleaning station 104. A first hot air distributor 130 extends in the Y direction to the right of the first cleaning fluid distributor 124. A second cleaning fluid distributor 124 extends in the Y direction to the right of the first hot air distributor 130. A second hot air distributor 130 extends in the Y direction to the right of the second cleaning fluid distributor 124. A third cleaning fluid distributor 124 extends in the Y direction to the right of the second hot air distributor 130 along the right end of the cleaning station 104.

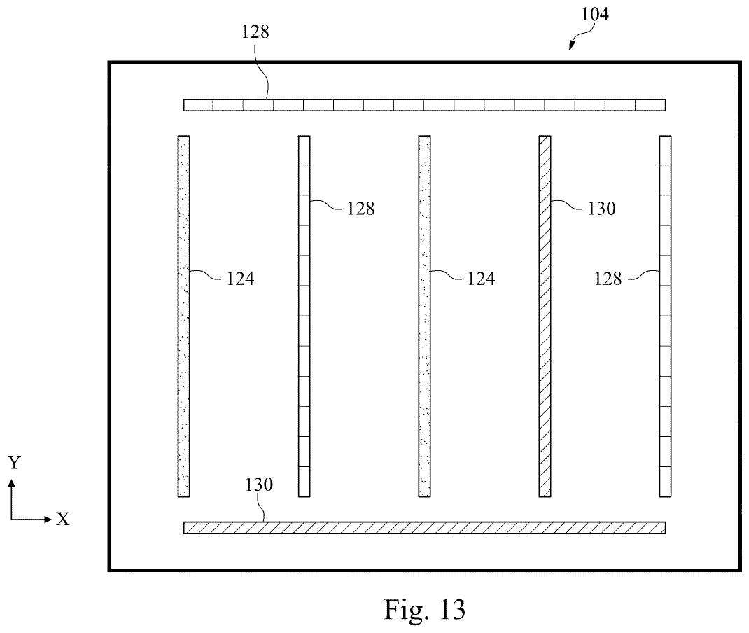

FIG. 13 is a top view of a layout of cleaning fluid distributors 124, heaters 128, and hot air distributors 130 within a cleaning station 104, in accordance with some embodiments. In FIG. 13, a heater 128 and a hot air distributor 130 extend in the X direction along opposite sides of the interior volume of the cleaning station 104. A first cleaning fluid distributor 124 extends in the Y direction at the left end of the cleaning station 104. A first heater 128 extends in the Y direction to the right of the first cleaning fluid distributor 124. A second cleaning fluid distributor 124 extends in the Y direction to the right of the first heater 128. A first hot air distributor 130 extends in the Y direction to the right of the second cleaning fluid distributor 124. A second heater 128 extends in the Y direction to the right of the first hot air distributor 130 along the right end of the cleaning station 104.

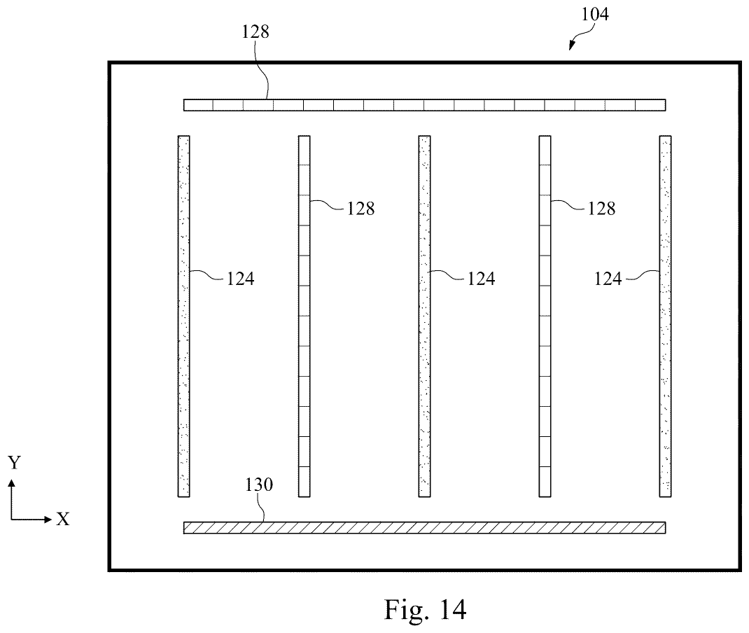

FIG. 14 is a top view of a layout of cleaning fluid distributors 124, heaters 128, and hot air distributors 130 within a cleaning station 104, in accordance with some embodiments. In FIG. 14, a heater 128 and a hot air distributor 130 extend in the X direction along opposite sides of the interior volume of the cleaning station 104. A first cleaning fluid distributor 124 extends in the Y direction at the left end of the cleaning station 104. A first heater 128 extends in the Y direction to the right of the first cleaning fluid distributor 124. A second cleaning fluid distributor 124 extends in the Y direction to the right of the first heater 128. A second heater 128 extends in the Y direction to the right of the second cleaning fluid distributor 124. A third cleaning fluid distributor 124 extends in the Y direction to the right of the second heater 128 along the right end of the cleaning station 104.

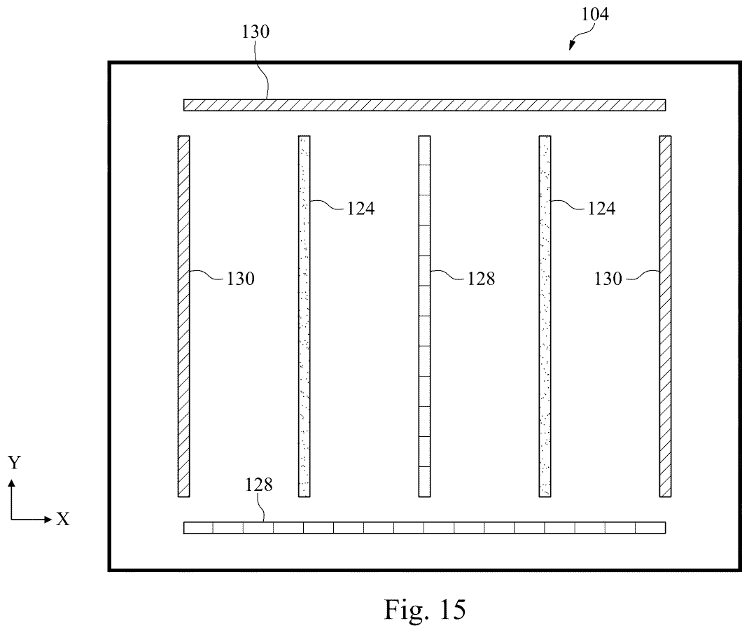

FIG. 15 is a top view of a layout of cleaning fluid distributors 124, heaters 128, and hot air distributors 130 within a cleaning station 104, in accordance with some embodiments. In FIG. 15, a heater 128 and a hot air distributor 130 extend in the X direction along opposite sides of the interior volume of the cleaning station 104. A first hot air distributor 130 extends in the Y direction at the left end of the cleaning station 104. A first cleaning fluid distributor 124 extends in the Y direction to the right of the first hot air distributor 130. A first heater 128 extends in the Y direction to the right of the first cleaning fluid distributor 124. A second cleaning fluid distributor 124 extends in the Y direction to the right of the first heater 128. A second hot air distributor 130 extends in the Y direction to the right of the second cleaning fluid distributor 124 along the right end of the cleaning station 104.

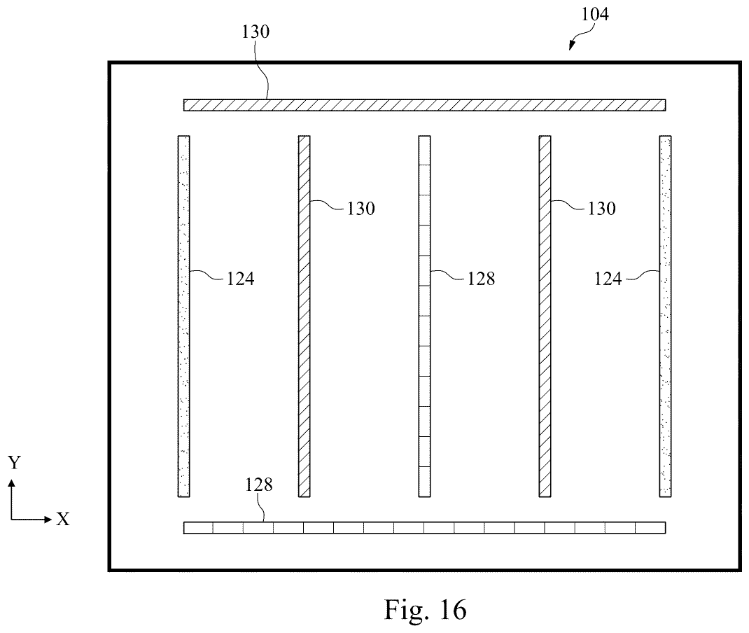

FIG. 16 is a top view of a layout of cleaning fluid distributors 124, heaters 128, and hot air distributors 130 within a cleaning station 104, in accordance with some embodiments. In FIG. 16, a heater 128 and a hot air distributor 130 extend in the X direction along opposite sides of the interior volume of the cleaning station 104. A first cleaning fluid distributor 124 extends in the Y direction at the left end of the cleaning station 104. A first hot air distributor 130 extends in the Y direction to the right of the first cleaning fluid distributor 124. A first heater 128 extends in the Y direction to the right of the first hot air distributor 130. A second hot air distributor 130 extends in the Y direction to the right of the first heater 128. A second cleaning fluid distributor 124 extends in the Y direction to the right of the second hot air distributor 130 along the right end of the cleaning station 104. In some embodiments, in FIGS. 7-16 the cleaning fluid distributors 124, heaters 128, and hot air distributors 130 that extend in the X direction have a length in the X direction between 3 cm and 80 cm. In some embodiments, in FIGS. 7-16 the cleaning fluid distributors 124, heaters 128, and hot air distributors 130 that extend in the Y direction have a length in the Y direction between 3 cm and 80 cm. Other dimensions can be utilized without departing from the scope of the present disclosure.

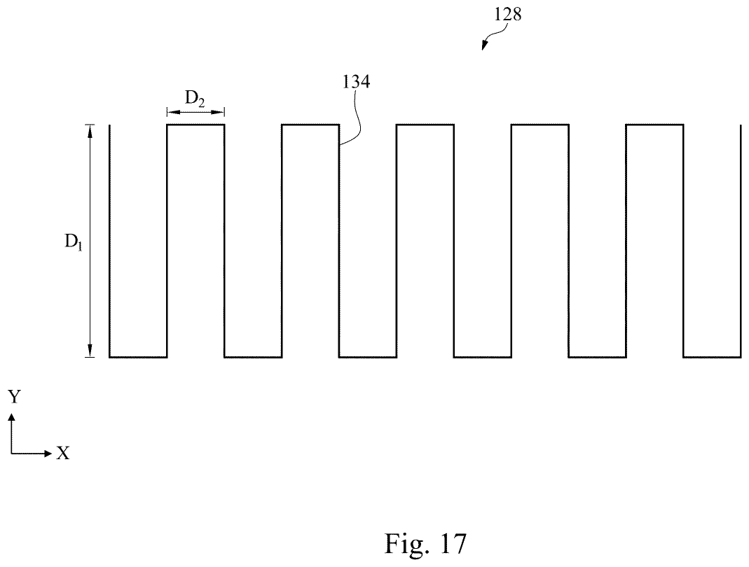

FIG. 17 is an illustration of a heater 128, in accordance with some embodiments. The heater 120 is a heating coil. The heating coil has a plurality of segments extending in the Y direction and having a dimension D1. The heating coil has a plurality of segments extending in the X direction and having a dimension D2. In some embodiments, D1 is between 3 cm and 80 cm. In some embodiments, D2 is between 0.1 cm and 5 cm. Other dimensions can be utilized without departing from the scope of the present disclosure.

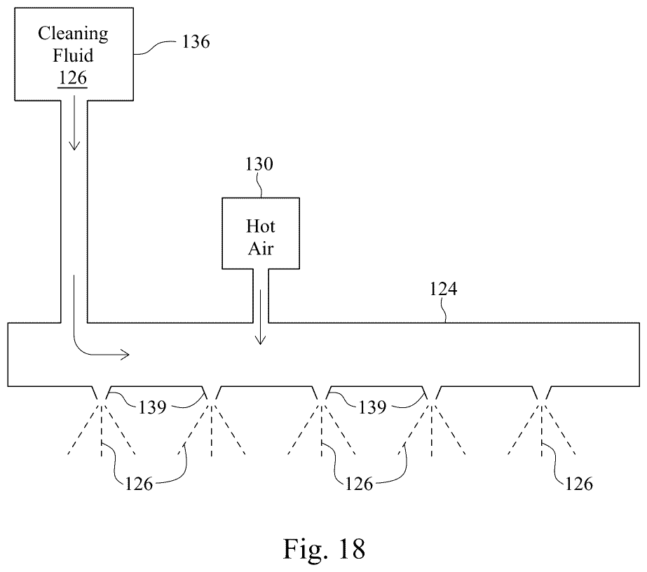

FIG. 18 is an illustration of a cleaning fluid distributor 124, in accordance with some embodiments. The cleaning fluid distributor 124 of FIG. 18 is one example of a cleaning fluid distributor 124 of FIGS. 2-16. In FIG. 18, cleaning fluid distributor 124 is a spray bar. A cleaning fluid reservoir 136 supplies the cleaning fluid 126 into the spray bar. A hot air distributor 130 flows hot air into the spray bar to mix with the cleaning fluid 126. This elevates the temperature of the cleaning fluid 126. The heated cleaning fluid 126 is then output from a plurality of nozzles of the spray bar. Accordingly, in some embodiments, the hot air distributor 130 conditioner hot air into the cleaning fluid distributor 124 upstream from the nozzles.

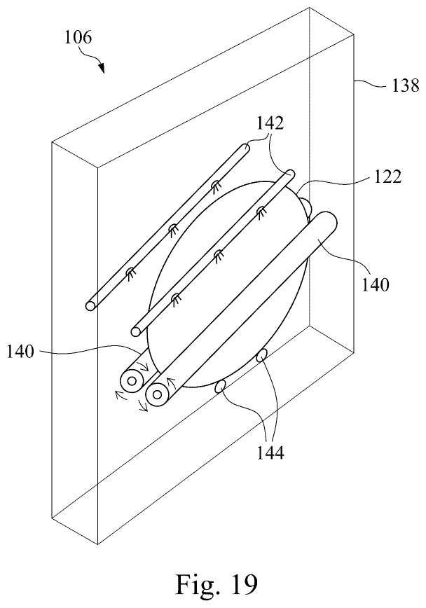

FIG. 19 is an illustration of a brush station 106 of a CMP station 100, in accordance with some embodiments. The brush station 106 of FIG. 19 is one example of a brush station 106 of FIG. 1. A robot arm lowers the wafer 122 into the brush box 138. The brush box 138 includes roller brushes 140. The wafer 122 is positioned between the roller brushes 140. The roller brushes 140 rotate and clean the surfaces of the wafer 122. The brush box 138 also includes rollers 144 that rotate the wafer 122 while the roller brushes 140 clean the wafer. The roller brushes 140 are made from a nonabrasive, soft material that will not damage the surface of the wafer 122. The brush box 138 also includes chemical spray bars 142. The chemical spray bars 142 include apertures or nozzles that spray a cleaning chemical onto the surfaces of the wafer 122.

As described previously, the wafer 122 is passed to the brush station 106 after the cleaning station 104. As set forth previously, because of the heating at the cleaning station 104, the services of the wafer 122 are substantially free from metal oxides, and other undesirable contaminants or particles. The result is that the brushes 140 do not become loaded with metal oxides, and other undesirable contaminants or particles. This helps ensure that the brush station 106 can continue to operate.

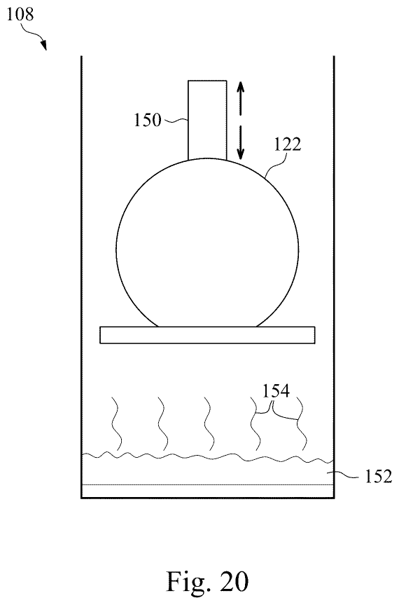

FIG. 20 is an illustration of dryer station 108 of a CMP system 100, in accordance with some embodiments. The dryer station 108 of FIG. 20 is one example of a dryer station 108 of FIG. 1. In some embodiments, the dryer station 108 is a vapor dryer. The wafer 122 is positioned on a lift 150. The lift 150 raises and lowers the wafer 122 within the dryer station 108.

The dryer station 108 includes a pool of a liquid chemical 152. The dryer station 108 also includes a heater 186. The heater 186 heats the liquid chemical 152. The heating of the liquid chemical 152 generates a vapor 154 from the liquid chemical 152. The vapor 154 rises up within the dryer station 108. The lift 150 lowers the wafer 122 into the vapor 154. The vapor 154 has the effect of pushing deionized water and other chemicals off of the surface of the wafer 122. This is accomplished due to the different surface tensions of the vapor and the remaining deionized water or other chemicals. In one example, the liquid chemical 152 is isopropyl alcohol. Accordingly, the vapor 154 is an isopropyl alcohol vapor. The isopropyl alcohol vapor dries the surface of the wafer 122 by pushing remaining deionized water and other chemicals off of the surface of the wafer 122. As set forth previously, the wafer 122 is transported to the dryer station 108 after the wafer 122 has been processed at the cleaning station 104 and one or more brush stations 106.

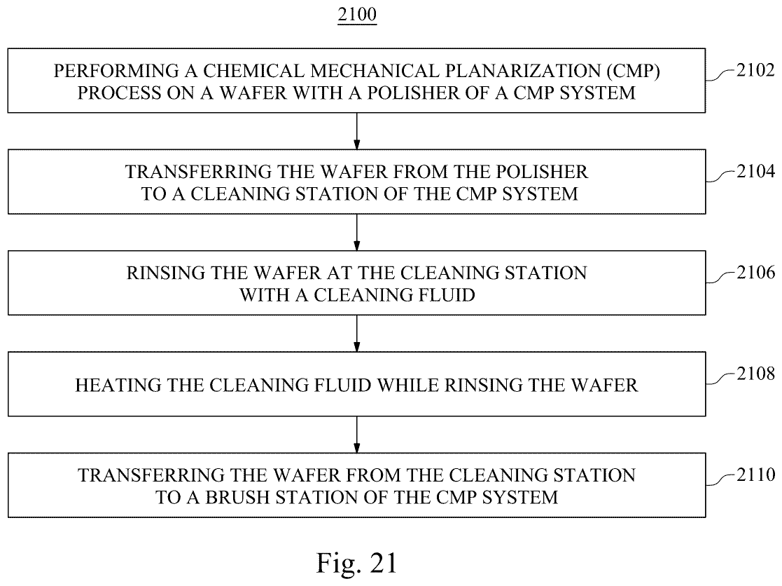

FIG. 21 is a flow diagram of a method 2100, in accordance with some embodiments. The method 2100 can utilize processes, components, and systems described in relation to FIGS. 1-20. At 2102, the method 2100 includes performing a CMP process on a wafer with a polisher of a CMP system. One example of a polisher is the polisher 102 of FIG. 1. One example of a wafer is the wafer 122 of FIG. 2. At 2102, the method 2100 includes transferring the wafer from the polisher to a cleaning station of the CMP system. One example of a cleaning station is the cleaning station 104 of FIG. 1. At 2106, the method 2100 includes rinsing the wafer at the cleaning station with a cleaning fluid. One example of a cleaning fluid is the cleaning fluid 126 of FIG. 2. At 2108, the method 2100 includes heating the cleaning fluid while rinsing the wafer. At 2110, the method 2100 includes transferring the wafer from the cleaning station to a brush station of the CMP system. One example of a brush station is the brush station 106 of FIG. 1.

Embodiments of the present disclosure provide a cleaning station for a CMP system, in accordance with some embodiments. After a CMP process, it is possible that an exposed metal layer can oxidize. Furthermore, it is possible that debris or other unwanted particles or contaminants can remain on the surface of the wafer after the CMP process. After a CMP process has been performed on a wafer, the wafer is passed to a cleaning station. The cleaning station rinses the wafer with a cleaning fluid. The cleaning station, in accordance with embodiments of the present disclosure, includes a heating system that heats the cleaning fluid or that heats the interior of the cleaning station while the wafer is being rinsed. The elevated temperature results in a greatly increased ability of the cleaning fluid to remove metal oxides and other debris from the surface of the wafer. The heating system can include one or both of a heater that radiates heat and a device that blows hot air into the cleaning station. This elevates a temperature of the cleaning fluid, resulting in an increased ability of the cleaning fluid to remove metal oxides and to clean debris from the surface of the wafer.

Embodiments of the present disclosure provide many benefits over traditional cleaning stations of CMP systems. For example, after the wafer has been cleaned by the cleaning station, the wafer is passed to a brush station the uses one or more brushes to further condition the surface of the wafer. If there are debris particles or metal oxides on the surface of the wafer, it is possible that the brushes will become heavily contaminated or loaded with metal oxide particles are debris particles. This could result in stoppage of the CMP system until the brushes can be cleaned or replaced. Embodiments of the present disclosure help ensure that the brushes are not contaminated and that CMP processes are not interrupted. Furthermore, semiconductor wafer yields are increased and integrated circuits formed in the semiconductor wafers function properly.

In some embodiments, a method includes performing CMP process on a wafer with a polisher of a CMP system and transferring the wafer from the polisher to a cleaning station of the CMP system. The method includes rinsing the wafer at the cleaning station with a cleaning fluid, heating the cleaning fluid while rinsing the wafer, and transferring the wafer from the cleaning station to a brush station of the CMP system.

In some embodiments, a CMP system includes a polishing station configured to perform a CMP process on a wafer and a cleaning station configured to receive the wafer from the polishing station. The cleaning station includes a rinsing system configured spray a cleaning fluid onto the wafer and a heating system configured to heat the cleaning fluid. The CMP system includes a brush station configured to receive the wafer from the cleaning station.

In some embodiments, a CMP cleaning station includes a housing, an opening configured to receive a wafer into the housing, and a cleaning fluid distributor configured to spray a rinsing fluid. The cleaning station includes a first heater configured to heat the cleaning fluid and a second heater configured to heat the cleaning fluid.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing a chemical mechanical planarization (CMP) process on a wafer with a polisher of a CMP system;
transferring the wafer from the polisher to a cleaning station of the CMP system;
rinsing the wafer at the cleaning station with a cleaning fluid;
heating the cleaning fluid while rinsing the wafer; and
transferring the wafer from the cleaning station to a brush station of the CMP system.

2. The method of claim 1, wherein the cleaning fluid is deionized water.

3. The method of claim 1, wherein the cleaning fluid is a cleaning chemical.

4. The method of claim 1, wherein heating the cleaning fluid includes activating a halogen lamp within an interior volume of the cleaning station.

5. The method of claim 1, wherein heating the cleaning fluid includes passing an electric current through a heating coil within an interior volume of the cleaning station.

6. The method of claim 1, wherein heating the cleaning fluid includes blowing a heated gas into an interior volume of the cleaning station.

7. The method of claim 1, wherein heating the cleaning fluid includes heating the cleaning fluid to a temperature between 55 °C and 65 °C.

8. The method of claim 1, wherein heating the cleaning fluid includes:
activating a radiative heater within an interior volume of the cleaning station; and
blowing heated gas into the interior volume of the cleaning station.

9. The method of claim 1, wherein:
rinsing the wafer includes spraying the cleaning fluid onto the wafer from a nozzle of a cleaning fluid distributor; and
heating the cleaning fluid includes introducing heated gas into the cleaning fluid distributor upstream from the nozzle.

10. The method of claim 1, further comprising:
transferring the wafer from the brush station to a vapor drying station of the CMP system; and
drying the wafer with the vapor drying station.

11. A chemical mechanical planarization (CMP) system, comprising:
a polishing station configured to perform a CMP process on a wafer;
a cleaning station configured to receive the wafer from the polishing station, the cleaning station including:
a rinsing system configured spray a cleaning fluid onto the wafer; and
a heating system configured to heat the cleaning fluid; and
a brush station configured to receive the wafer from the cleaning station.

12. The CMP system of claim 11, wherein the heating system includes a first heater and a second heater laterally surrounding the first heater.

13. The CMP system of claim 11, wherein:
the rinsing system includes a cleaning fluid distributor; and
the heating system includes a heater laterally surrounded by the cleaning fluid distributor.

14. The CMP system of claim 11, wherein:
the rinsing system includes a cleaning fluid distributor; and
the heating system includes a heater laterally surrounding the cleaning fluid distributor.

15. The CMP system of claim 11, wherein:
the rinsing system includes a first cleaning fluid distributor and a second cleaning fluid distributor each extending in a first direction; and
the heating system includes a first heater and a second heater each extending in a second direction between the first cleaning fluid distributor and the second cleaning fluid distributor.

16. The CMP system of claim 11, wherein:
the heating system includes a first heater and a second heater each extending in a first direction; and
the rinsing system includes a first cleaning fluid distributor and a second cleaning fluid distributor each extending in a first direction between the first and second heater.

17. The CMP system of claim 16, wherein the heater includes a third heater extending in the second direction between the first heater and the second heater.

18. A chemical mechanical planarization (CMP) cleaning station, comprising:
a housing;
an opening configured to receive a wafer into the housing;
a cleaning fluid distributor configured to spray a cleaning fluid;
a first heater configured to heat the cleaning fluid; and
a second heater configured to heat the cleaning fluid.

19. The CMP system of claim 18, wherein the first heater is a radiative heater and the second heater blows a heated gas into an interior of the housing.

20. The CMP system of claim 18, wherein:
the first cleaning fluid distributor includes a nozzle configured to spray the cleaning fluid; and
the first heater is configured to introduce a heated gas into the cleaning fluid distributor upstream from the nozzle.
